(19) United States
(12) Patent Application Publication
(10) Pub. No.: US 2024/0429342 A1
(43) Pub. Date: Dec. 26, 2024

(54) METHOD FOR SINGULATING A SEMICONDUCTOR COMPONENT HAVING A PN JUNCTION AND SEMICONDUCTOR COMPONENT HAVING A PN JUNCTION

(71) Applicant: Fraunhofer-Gesellschaft zur Förderung der angewandten Forschung e.V., Munchen (DE)

(72) Inventors: Elmar Lohmüller, Freiburg (DE); Ralf Preu, Freiburg (DE); Puzant Baliozian, Freiburg (DE); Tobias Fellmeth, Freiburg (DE); Nico Wöhrle, Freiburg (DE); Pierre Saint-Cast, Freiburg (DE); Armin Richter, Freiburg (DE)

(73) Assignee: Fraunhofer-Gesellschaft zur Förderung der angewandten Forschung e.V., Munchen (DE)

(21) Appl. No.: 18/822,954

(22) Filed: Sep. 3, 2024

Related U.S. Application Data
(63) Continuation-in-part of application No. 17/279,158, filed on Mar. 24, 2021.

(30) Foreign Application Priority Data
Sep. 24, 2018 (DE) 102018123484.8

(51) Int. Cl. H01L 31/20; H01L 31/0747

(52) U.S. Cl. CPC H01L 31/208; H01L 31/0747

(57) ABSTRACT

A semiconductor component having at least one emitter, at least one base, and a pn junction formed between emitter and base, having at least one non-metallic transverse conduction layer for the transverse conduction of majority charge carriers of the emitter. The emitter includes the transverse conduction layer and/or the transverse conduction layer is formed parallel to the emitter and in a manner electrically conductively connected thereto, and having a break side, at which the semiconductor component was singulated. A transverse conduction avoidance region is formed and arranged at the break side such that the transverse conductivity is reduced by at least a factor of 10, wherein the transverse conduction avoidance region has a depth (TQ) in the range of 5 μm to 500 μm, in particular 10 μm to 200 μm, perpendicular to the break side. A method for singulating a semiconductor component is also provided.

### CROSS REFERENCE TO RELATED APPLICATIONS

This application is a continuation-in-part of U.S. patent application Ser. No. 17/279,158, filed on Mar. 24, 2021, which claims the benefit of PCT Application No. PCT/EP/2019075597 filed on Sep. 24, 2019, which claims the benefit of German Application No. DE102018123484.8 filed on Sep. 24, 2018, which are incorporated by reference as if fully set forth.

### TECHNICAL FIELD

The invention relates to a method for singulating a semiconductor component comprising a pn junction and a semiconductor component comprising a pn junction.

### BACKGROUND

In the production of semiconductor components, it is often desirable to singulate a plurality of semiconductor components produced on a substrate by virtue of the substrate being separated at at least one separating surface such that the semiconductor components are separated. Such singulation is necessary during the production of computing processors since a multiplicity of computing processors are typically produced on one silicon wafer. Moreover, there is increased use of a singulation of photovoltaic solar cells.

These days, photovoltaic modules are usually produced from silicon solar cells with an edge length of approximately 156 mm. Interconnection is implemented by electrically conductive connections by conducting elements—usually so-called cell connectors—which each connect solar cells on the front and back side in alternating fashion. A disadvantage of this interconnection is that the high current (up to approximately 10 A) of the individual solar cells requires a very high conductivity and consequently large conduction cross sections of the cell connectors.

A known option for circumventing this disadvantage lies in the provision of two or more solar cells on one silicon wafer in order to proportionally reduce the current per solar cell accordingly. These are only singulated toward the end of the processing in order for production to be able to use the large initial wafers as long as possible, and hence keep productivity high and be able to use established production equipment.

If furthermore, as described above, the solar cells are electrically connected by cell connectors, a space which is not photovoltaically active and hence leads to reduction in the module efficiency remains between the solar cells.

A known process for circumventing this disadvantage lies in the so-called shingling of the solar cells, in which the top side of one end of a solar cell is directly electrically connected to the bottom side of the next cell. To this end, the external contacts on the front and back side are realized at the respective opposite edges of the solar cells. Since usually no highly conductive contact elements are present in the solar cell so as to minimize the shadowing and since the paths along which the current must flow in the contact fingers to the outer lying external contacts are very long for the shingling concept on the basis of large conventional solar cells, the silicon wafers are cut into thin strips following the processing of the solar cells such that, consequently, a plurality of photovoltaic solar cells with a typically rectangular form are realized in order to minimize power losses in the finger contacts of the solar cell in the case of shingling.

The singulation of the semiconductor components produced on a substrate, in particular on a silicon wafer, leads to an increase in the ratio of perimeter to area, and hence to an increase of area-normalized power losses due to edge recombination. Investigations have shown (J. Dicker, “Analyse und Simulation von hocheffizienten Silizium-Solarzellenstrukturen für industrielle Fertigungstechniken”, Dissertation, University of Konstanz, 2003) that power losses arise, in particular, in the region where a pn junction meets a separating surface where singulation occurred. A reason for this, in particular, lies in the edge recombination in the quasi-neutral areas of emitter and base and, as described above, in the space charge region in particular. Additionally, the separation of the singulated semiconductor components at the produced edges leads to a significant increase in the recombination rate itself. This influence is particularly relevant if the semiconductor component has a high electronic quality on the other surfaces, in particular a lower recombination rate as a result of passivation layers or other passivation mechanisms.

There therefore is a need for singulating semiconductor components without substantially reducing the electronic quality of the semiconductor component due to the separating surface, in particular due to recombination effects at the separating surface.

Forming strong doping which completely passes through the semiconductor substrate in the region of the separating surface and then performing the singulation within this strong doping, such that a region of strong doping is respectively formed at the separating surfaces following singulation, is known for the purposes of avoiding such negative electronic properties at the separating surface (W. P. Mulligan, A. Terao, D. D. Smith, P. J. Verlinden, and R. M. Swanson, “Development of chip-size silicon solar cells”, in Proceedings of the 28th IEEE Photovoltaic Specialists Conference, Anchorage, USA, 2000, pp. 158-163). This procedure is disadvantageous in that forming the strong doping is very time-consuming and consequently unsuitable for industrial production.

Furthermore, the formation of so-called emitter windows is known (D. Konig, and G. Ebest, “New contact frame design for minimizing losses due to edge recombination and grid-induced shading”, Solar Energy Materials and Solar Cells, vol. 75, no. 3-4, pp. 381-386, 2003). Here, during the production of the emitter by masking methods and/or by selective application of a doping source, such as a doping paste, the emitter is formed in such a way that the pn junction does not directly border the separating surface but that there is a distance of a few ten micrometers between pn junction and separating surface. However, additional masking steps are required to form the emitter window, and so the production requires more time and is more expensive.

Furthermore, the production of isolation trenches by laser ablation, by locally applied etching pastes by way of printing technology (e.g., dispensing, extrusion, screen printing, inkjet) or alternative structuring methods in the cell surface is known, in order to minimize the influence on the semiconductor component of the highly recombinant areas at the separating surface. Consequently, the isolation trenches are spaced apart from the separating surface and electrically separate an edge emitter region no longer available for the function of the semiconductor component from the interior constituent part of the semiconductor component. A disadvantage of these methods is that such processes are typically only possible in the so-called front-end, and consequently during a stage of the production process in which the semiconductor component, in particular the solar cell, has not yet been passivated and metallized since high temperature processes are typically required to passivate the isolation trenches (M. D. Abbott, J. E. Cotter, T. Trupke, and R. A. Bardos, “Investigation of edge recombination effects in silicon solar cell structures using photoluminescence”, Applied Physics Letters, vol. 88, no. 11, p. 114105, 2006).

### SUMMARY

The present invention is therefore based on the object of making available a method for singulating a semiconductor component comprising a pn junction and a semiconductor component comprising a pn junction such that a negative influence of the separating surface on the electronic quality is reduced and the disadvantages of the methods known in advance are avoided or at least reduced.

This object is achieved by a method and by a semiconductor component having one or more of the features disclosed herein. Advantageous embodiments are found in the following description and claims.

The method according to the invention is preferably embodied to produce a semiconductor component according to the invention, in particular a preferred embodiment thereof. The semiconductor component according to the invention is preferably formed by the method according to the invention, in particular in a preferred embodiment thereof.

The method according to the invention for singulating a semiconductor component comprising a pn junction includes the following method steps:

In a method step A, a semiconductor component having at least one emitter and at least one base, with a pn junction formed between emitter and base, and a non-metallic transverse conduction layer for transverse conduction of majority charge carriers of the emitter is provided, wherein the emitter comprises the transverse conduction layer and/or the transverse conduction layer is formed parallel to the emitter and electrically conductively connected to the latter.

In a method step B, the semiconductor component is singulated by separation into at least two partial elements at at least one separating surface.

What is essential is that between method steps A and B, in a method step B0, a transverse conduction avoidance region is formed in the transverse conduction layer in order to reduce the transverse conductivity by at least a factor of 10 and that, in method step B, the separating surface borders and/or passes through the transverse conduction avoidance region.

The invention is based on the discovery that the recombination in a semiconductor in general, and hence also at the separating surface, is proportional to the product between number of holes and electrons, and hence that the reduction in the electronic quality of the semiconductor component is substantially due to the transport mechanism of electrons and holes to the separating surface. Now, if the flow of either electrons or holes to the separating surface is curtailed or at least significantly reduced, a reduction in the electronic quality of the semiconductor component as a result of the separating surface, in particular as a result of recombination activities at the separating surface, is accordingly also avoided or at least significantly reduced. Thus, the flow of charge carriers in the emitter to the separating surface is curtailed or at least significantly reduced. If the respective recombination partner that is complementary to the base is missing at the separating surface, there is no recombination or the recombination is significantly reduced.

Now, in the method according to the invention, the transverse conduction avoidance region is formed prior to the singulation of the semiconductor component, said transverse conduction avoidance region reaching up to the separating surface and consequently at least bordering the latter, in particular being penetrated by the separating surface. On account of the transverse conductivity that has been reduced by at least a factor of 10, the negative influence of the separating surface on the electronic quality is avoided or at least significantly reduced, as described above, as a result of the transverse conduction avoidance region.

It is therefore advantageous to reduce the transverse conductivity by at least a factor of 10, in particular by at least a factor of 100, by the transverse conduction avoidance region. In particular, it is advantageous to completely curtail the transverse conduction of charge carries of the emitter in the transverse conduction avoidance region.

In the case of a multiplicity of semiconductor components, in particular in the case of photovoltaic solar cells with, for example, emitters produced by diffusion of doping atoms or by implantation, there is a transverse conduction of charge carriers substantially in the emitter. Typically, the transverse conduction occurs to metallic contacting structures which are connected in electrically conductive fashion to the emitter for the purposes of supplying or (in the case of photovoltaic solar cells) carrying away the majority charge carriers.

In an n-type doping emitter, the electrons represent the majority charge carriers and, correspondingly, the holes in the case of a p-type doping emitter.

Emitter structures that have no transverse conductivity, or only a small transverse conductivity, are also known. Thus, the use of so-called hetero emitters, in which a thin intrinsic layer is formed between emitter and base, is known. In particular, solar cell structures in which a hetero emitter is formed by a doped emitter layer made of amorphous silicon are known. Such doped silicon layers made of amorphous silicon only have a low transverse conductivity, which is why a layer with a high transverse conductivity, i.e., a low transverse conduction resistance, for example a transparent conducting oxide (TCO), is typically applied adjacent to the emitter layer. In this case, the transverse conduction of the majority charge carriers of the emitter consequently takes place substantially outside of the doped emitter layer and the aforementioned TCO layer represents the transverse conduction layer.

As described above, what is essential to the method according to the invention is that the transverse conduction of the charge carriers of the emitter to the separating surface is curtailed. Accordingly, the transverse conduction avoidance region is formed at least in the transverse conduction layer and consequently, for example, in the aforementioned TCO layer in the case of a hetero emitter or in the doped emitter layer itself in the case of a diffused or implanted emitter, as described above.

The method according to the invention is advantageous in that it can be implemented in the production process in cost-effective fashion and, in particular, the singulation can be applied at the end of the manufacturing process such that it is possible to profit from cost-effective large-area processing of the substrate, in particular a silicon wafer, during the production process.

Therefore, method step B0 is preferably carried out after the emitter is formed and possibly after a non-metallic transverse conduction layer is formed, provided the latter is located outside of the emitter, for example a TCO layer, and particularly preferably before passivation layers are formed. In addition and/or as an alternative thereto, method step B0 is preferably carried out before a metallic contacting structure, which is electrically conductively connected to the emitter, is applied.

The object specified at the outset is furthermore achieved by a semiconductor component as claimed in claim 13. The semiconductor component according to the invention comprises at least one emitter and at least one base, wherein a pn junction is formed between emitter and base, and comprises at least one non-metallic transverse conduction layer for transverse conduction of majority charge carriers of the emitter, wherein the emitter comprises the transverse conduction layer and/or the transverse conduction layer is formed parallel to the emitter and electrically conductively connected to the latter. The semiconductor component represents a singulated semiconductor component, comprising a break side at which the semiconductor component was singulated. What is essential is that a transverse conduction avoidance region is formed and arranged at the break side in such a way that the transverse conductivity is reduced by at least a factor of 10, wherein the transverse conduction avoidance region has a depth perpendicular to the break side ranging from 5 μm to 500 μm, in particular from 10 μm to 200 μm.

As a result of this, the advantages specified above in relation to the method according to the invention are achieved.

Advantageously, the transverse conduction region is formed as a separating trench, which reduces the thickness of the transverse conduction layer. What this achieves in a simple manner is a reduction in the transverse conductivity of the transverse conduction layer and hence an increase in the transverse conduction resistance since a smaller thickness results in a higher transverse conduction resistance.

Preferably, the thickness of the transverse conduction layer in the transverse conduction avoidance region is reduced by at least a half, preferably by at least 80%.

In particular, it is advantageous for the separating trench to be formed so as to pass through the pn junction. This additionally avoids an adjacency of the pn junction, and hence of the space charge region, at the separating surface and hence curtails the negative effects set forth at the outset.

Advantageously, the separating trench has a depth which is at least 10%, in particular at least 20%, preferably at least 40% of the thickness of the semiconductor component. As a result of this, a separation can be implemented more easily in method step B; in particular, the separating trench can serve as a predetermined breaking point.

To avoid breaking apart in the region of the separating trench in the process steps leading up to method step B, it is advantageous if the ends of the separating trench are each spaced apart from the edges of the semiconductor component, in particular have a distance ranging from 0.25 mm to 20 mm, preferably 0.5 mm to 5 mm. The regions between the ends of the separating trench and the edges of the substrate of the semiconductor components prior to singulation consequently stabilize the wafer before method step B. Preferably, in method step B, the separating trench is extended before the semiconductor component is singulated such that the ends of the separating trench have a distance of less than 0.3 mm, in particular less than 0.1 mm from the edges of the semiconductor component, in particular such that the ends of the separating trench reach up to the edges of the semiconductor component. This neutralizes the stabilizing effect and the separation can be implemented more easily.

In particular, it is advantageous that between method step B0 and B, in a method step B1, a passivation layer is applied to the separating trench, said passivation layer at least covering the pn junction bordering the separating trench. Consequently, this prevents the pn junction from bordering the separating surface and this causing a reduction in the electronic quality of the semiconductor component. Moreover, a negative effect of the adjacency of the pn conjunction at the surface of the separating trench is avoided or at least reduced by virtue of applying a passivation layer. The passivation layer preferably is a dielectric layer, particularly preferably a layer with stationary charges, particularly preferably with a surface charge density with an absolute value greater than or equal to 10¹² cm².

As described above, some emitter structures have only a low transverse conductivity, i.e., a high transverse conduction resistance, and the transverse conduction layer is therefore formed parallel to the emitter but separately from the emitter in the case of such structures, like the aforementioned TCO layer as transverse conduction layer, for example. In this case, the transverse conduction layer is consequently outside of the emitter.

In an advantageous embodiment, in which the transverse conduction layer is consequently arranged parallel to the emitter and formed separately therefrom, it is advantageous for the separating trench to be formed so as to reduce the thickness of the transverse conduction layer, in particular for the separating trench to be formed so as to pass through the transverse conduction layer.

In a manner known per se, the separating trench can be formed mechanically and/or chemically, in particular. Advantageously, the separating trench is formed by laser ablation and/or by local etching (e.g., etching paste applied by printing technology, in wet chemical fashion or by alternative etching media).

In particular, it is advantageous to carry out a post-treatment after the separating trench has been formed in order to reduce the surface recombination at the walls of the separating trench, in particular in the region where the pn junction borders the separating trench. Such a post-treatment is preferably implemented by wet chemical etching.

In a further advantageous embodiment of the method according to the invention, the material property of the transverse conduction layer is altered in the transverse conduction avoidance region for the purposes of reducing the transverse conductivity.

Consequently, in this context, too, the transverse conduction of charge carriers of the emitter to the separating area is avoided or at least reduced, without requiring a removal of the transverse conduction layer in the transverse conduction avoidance region.

Advantageously, the crystal structure of the material is altered in the transverse conduction avoidance region, particularly preferably by the local action of heat, preferably by a laser.

As an alternative or in addition thereto, the emitter is formed with an increased sheet resistance, preferably in the transverse conduction avoidance region, by virtue of the emitter having a lower effective doping concentration in the transverse conduction avoidance region. In particular, the emitter preferably has a sheet resistance in the transverse conduction avoidance region that is higher by at least a factor of 10.

In a preferred configuration, an increase in the emitter sheet resistance in the transverse conduction avoidance region is implemented by counter-diffusion: In the transverse conduction avoidance region, counter-diffusion is carried out using a dopant of an opposite doping type to the emitter doping. This reduces the effective doping concentration in the transverse conduction avoidance region and the sheet resistance is increased accordingly. Advantageously, the counter-diffusion is implemented after the emitter is formed.

The scope of the invention likewise includes the effective doping type of the transverse conduction avoidance region changing over to the doping type opposite to the doping type of the emitter as a result of the counter-diffusion. In this case, the transverse conduction avoidance region consequently has the opposite doping type to the emitter. Furthermore, the scope of the invention includes the counter-diffused region extending beyond the emitter depth.

Singulating the semiconductor component in method step B can be implemented in a manner known per se, in particular by one or more of the methods described below:
a) separation by a chip saw (W. P. Mulligan, A. Terao, D. D. Smith, P. J. Verlinden, and R. M. Swanson, “Development of chip-size silicon solar cells”, in Proceedings of the 28th IEEE Photovoltaic Specialists Conference, Anchorage, USA, 2000, pp. 158-163);
b) creation of a trench by a laser with subsequent mechanical breaking (M. Oswald, M. Turek, J. Schneider, and S. Schönfelder, “Evaluation of silicon solar cell separation techniques for advanced module concepts”, in Proceedings of the 28th European Photovoltaic Solar Energy Conference and Exhibition, Paris, France, 2013, pp. 1807-1812);
c) thermal laser separation (TLS): M. Oswald, M. Turek, J. Schneider, and S. Schönfelder, “Evaluation of silicon solar cell separation techniques for advanced module concepts”, in Proceedings of the 28th European Photovoltaic Solar Energy Conference and Exhibition, Paris, France, 2013, pp. 1807-1812; S. Eiternick, F. Kaule, H.-U. Zühlke, T. Kieβling, M. Grimm, S. Schoenfelder, and M. Turek, “High quality half-cell processing using thermal laser separation”, Energy Procedia, vol. 77, pp. 340-345, 2015.
d) laser induced cutting (LIC): S. Weinhold, A. Gruner, R. Ebert, J. Schille, and H. Exner, “Study of fast laser induced cutting of silicon materials”, in Proc. SPIE 8967, Laser Applications in Microelectronic and Optoelectronic Manufacturing (LAMOM), San Francisco, USA, 2014, 89671J.

Investigations have shown that it is particularly advantageous to use TLS or LIC to carry out the singulation in method step B. The TLS method is based on a short laser trench being created by a first laser beam, which then leads to a separation of the wafer by introduced thermomechanical stress on the basis of simultaneous heating (e.g., by a second laser beam) and cooling (e.g., by an air-water mixture) along the edge to be created in any direction. In particular, this allows a separating surface that is independent of the crystal orientation of the wafer to be separated. The LIC method is quite similar to the TLS method but without active cooling tracking the heating (e.g., by a laser beam) in LIC. The LIC method is also known as the LDC (laser direct cleaving) method.

### BRIEF DESCRIPTION OF THE DRAWINGS

Further advantageous features and embodiments of the present invention are explained below on the basis of exemplary embodiments and the figures. In detail:

FIGS. 1A-1E show sectional illustrations of five exemplary embodiments of semiconductor components according to the invention;

FIG. 2 shows a plan view from above on a semiconductor wafer for elucidating the position of the separating surfaces, and

FIG. 3 shows a plan view from above on a semiconductor wafer with separating trenches, the ends of which are spaced apart from the edges of the semiconductor component.

### DETAILED DESCRIPTION

The figures show schematic illustrations that are not true to scale. In particular, the widths and the thicknesses of the individual layers do not correspond to the actual conditions in order to provide a better representation.

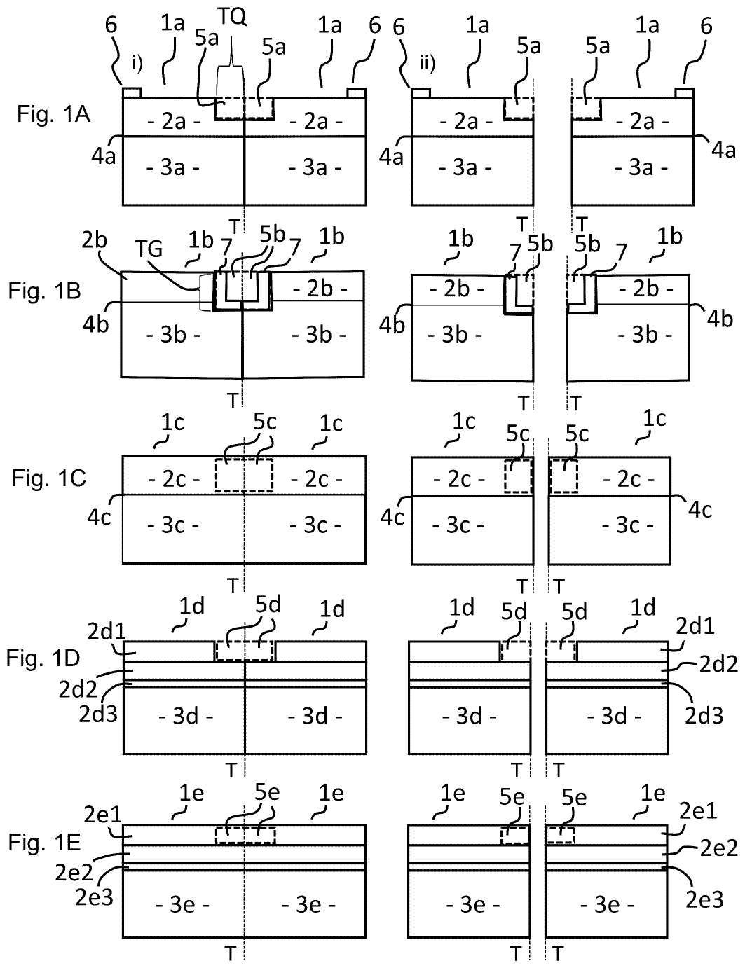

FIGS. 1A-1E show five exemplary embodiments A-E. For each exemplary embodiment, the left-hand column i) respectively illustrates the state before singulation and the right-hand column ii) respectively illustrates the state after singulation.

Semiconductor components in the form of photovoltaic solar cells are mentioned below as exemplary embodiments. Likewise, the illustrated semiconductor components could be formed as transistors in a modification of the exemplary embodiments.

A first exemplary embodiment of a method according to the invention is explained below on the basis of the first exemplary embodiment of a semiconductor component 1a according to the invention illustrated in FIG. 1A).

In a method step A, the semiconductor component 1a is provided. In the present case, it comprises an n-doping type emitter 2a formed from the vapor phase by diffusion and, accordingly, a base 3a, which is doped with a p-doping type dopant. Accordingly, a pn junction 4a is formed between emitter 2a and base 3a. Emitter and base were formed in a silicon wafer. In a modification of the exemplary embodiment, the emitter is formed by diffusion from a doping layer applied in advance or by implantation. Likewise, the doping types of emitter and base can be interchanged.

In a method step B0, a transverse conduction avoidance region 5a is formed in the transverse conduction layer, i.e., in the emitter 2a in the present case. The transverse conduction avoidance region borders a separating surface T, where singulation should subsequently take place. The transverse conduction avoidance region is formed perpendicular to the break side and consequently perpendicular to the separating surface T with a depth TQ ranging from 5 μm to 500 μm, 100 μm in the present case.

As is evident in FIG. 1A, at i, two transverse conduction avoidance regions 5a are formed in symmetric fashion on both sides of the separating surface T and form a common transverse conduction avoidance region in this state, which, following separation, is accordingly separated into two transverse conduction avoidance regions 5a. In the present case, the transverse conduction avoidance region 5a is formed as a separating trench, in which the thickness of the emitter 2a was reduced by 80% by laser ablation. This achieved an increase in the transverse conduction resistance of the emitter by a factor of 100 in the region of the transverse conduction avoidance region, i.e., in the region of the thinned emitter, and consequently achieved a reduction in the transverse conductivity by a factor of 100.

Subsequently, additional components, known per se, of a solar cell are produced: This comprises passivation layers 7 on the front side, located at the top, and at the back side, located at the bottom, metallization structures at the front side and back side for carrying away charge carriers and antireflection coatings at the front side and possibly back side for increasing the light absorption. These components have not been illustrated to provide a better overview.

Consequently, there is a transverse conduction of majority charge carriers in the emitter 2a to the front side metallic contacting structures 6, schematically illustrated, in this exemplary embodiment. The emitter 2a likewise represents the transverse conduction layer in this case.

Subsequently, a separation is implemented at the separating surface T in a method step B by the above-described TLS method. The separating surface T is perpendicular to the plane of the drawing in FIGS. 1A-1E and consequently passes through base 3a and emitter 2a.

The TLS method is carried out proceeding from the back side, i.e., firstly a laser is used to form an initial trench on the back side, located at the bottom, in the region where the separating line T intersects the back side. The initial trench starts at an edge of the semiconductor component. The initial trench does not extend over the entire width of the semiconductor component. Typical initial trenches have a length ranging from 200 μm to 4 mm, typically less than 2 mm. Subsequently, the semiconductor component is separated, as described above, by simultaneous heating and cooling.

The result is illustrated in FIG. 1A, at ii: Consequently, two mirror symmetric semiconductor components are produced, which each have a transverse conduction avoidance region 5a that borders the separating surface T.

To avoid repetition, only essential differences are discussed when explaining FIGS. 1B to 1E:

FIG. 1B illustrates a modification of the method as per FIG. 1A as a second exemplary embodiment of a method according to the invention, in which the transverse conduction avoidance region 5b, which is embodied as a separating trench, completely passes through the pn junction 4b between emitter 2b and base 3b. An etching procedure is carried out therefore between method step B0 and method step B, i.e., prior to singulation, in order to avoid possible damage to the walls of the separating trench. Furthermore, a silicon oxide layer is applied to the walls of the separating trench by thermal oxidation, said silicon oxide layer consequently also covering the pn junction 4b in the region where the latter borders the transverse conduction avoidance region. This further increases the electronic quality. The separating trench has a depth TG of several 100 nm to 50 μm, 20 μm in the present case, which consequently corresponds to 10% of the thickness in the case of a semiconductor component with a thickness of 200 μm.

The result of the separation at the separating surface T in method step B is illustrated in FIG. 1B, at ii. Consequently, two mirror image semiconductor components 1b also arise in this case.

In a third exemplary embodiment of the method according to the invention as per FIG. 1C, there is a modification to the extent of the transverse conduction avoidance region 5c in the emitter 2c being formed not as a separating trench but as a region of reduced emitter doping. This is obtained by virtue of implementing counter-diffusion in the transverse conduction avoidance region 5c: Like in the preceding exemplary embodiments, too, the emitter 2c is n-doped and the base 3c is p-doped. By introducing boron atoms by local diffusion (by heating, in particular local heating, preferably by a laser) from a doping medium containing the dopant, in particular a doping paste, into the transverse conduction avoidance region 5c, there is a reduction in the effective doping concentration of the emitter in the transverse conduction avoidance region 5c, and so, accordingly, an increase in the sheet resistance of the emitter and consequently an increase in the transverse conduction resistance of the emitter by a factor of 100 are obtained.

Consequently, following singulation in method step B (illustration in FIG. 1C, at ii), the current flow of charge carriers in the emitter 2c to the separating surface T is reduced on account of the increased emitter sheet resistance in the transverse conduction avoidance region 5c.

FIGS. 1D and E show a fourth and a fifth exemplary embodiment, in which the emitter is formed as a hetero emitter:

A base 3d, 3e, n-doped in the present case, is formed in a silicon wafer. A layer system is applied to the front side and comprises—proceeding from the base 3d, 3e—an intrinsic silicon layer (i-Si layer) 2d3, 2e3, an amorphous silicon layer (a-Si layer) 2d2, 2e2 and a transparent oxide layer (TCO layer) 2d1, 2e1.

Consequently, the emitter is formed as a hetero emitter by the a-Si layer and the i-Si layer. The a-Si layer (2d2, 2e2) only has a low transverse conductivity, i.e., a high transverse conduction resistance. To be able to carry away majority charge carriers by transverse conduction, the TCO layer 2d1, 2e1 is arranged therefore on the front side of the a-Si layer 2d2, 2e2. Consequently, the TCO layer represents the transverse conduction layer in these two exemplary embodiments.

Accordingly, a transverse conduction avoidance region 5d, 5e is formed in the TCO layer 2d1, 2e1 in method step B0.

In the fourth exemplary embodiment as per FIG. 1D, the transverse conduction avoidance region 5d is formed as a separating trench, in which the TCO layer 2d1 has been completely removed from the transverse conduction avoidance region 5d by laser ablation. As is evident from FIG. 1D, at ii, although the emitter still borders the separating surface T with the a-Si layer 2d2 and i-Si layer 2d3 in an unchanged manner after singulation, the TCO layer 2d1, however, is spaced apart from the separating surface T. Due to the above-described low transverse conductivity of the a-Si layer 2d2, the transverse conduction of charge carriers of the emitter to the separating surface is consequently also significantly reduced in this case.

In the fifth exemplary embodiment as per FIG. 1E, the transverse conduction avoidance region 5e is formed in such a way that the structure of the TCO is altered into a form of significantly reduced electrical conductivity by the action of heat; in particular, the crystalline structure is converted into a partly amorphous or amorphous structure. Even without changing the thickness of the TCO layer 2e1 in the transverse conduction avoidance region 5e, the transverse conduction resistance of the TCO layer is increased by a factor of 100 in the transverse conduction avoidance region 5e in this way.

In order to provide a better representation, FIGS. 1A-1E only illustrate one separating surface in each case.

When singulating photovoltaic solar cells, for example to form modules in accordance with the shingling technique mentioned at the outset, there usually is a singulation into a plurality of solar cells starting from a silicon wafer.

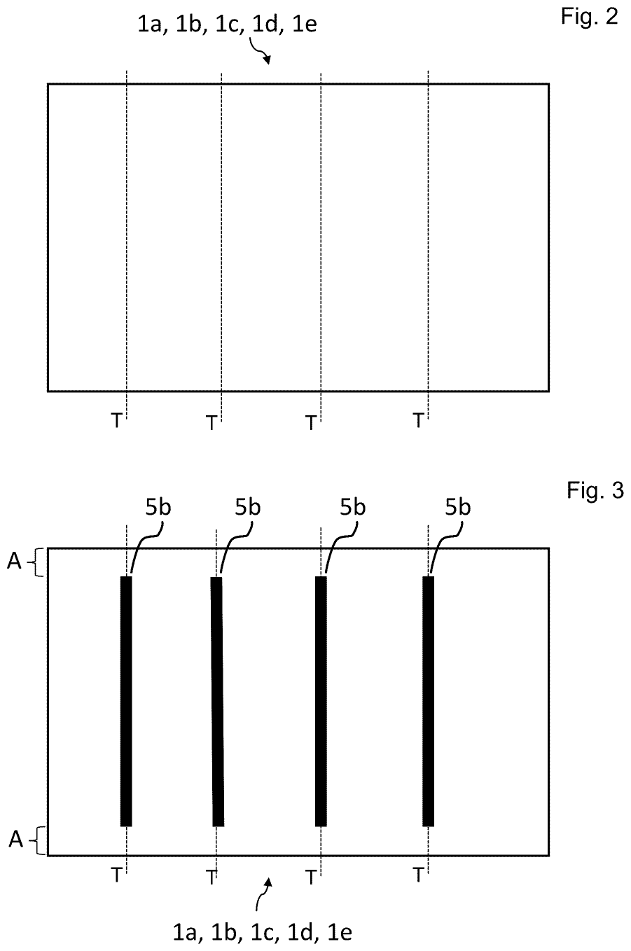

FIG. 2 illustrates a schematic plan view from above on a silicon wafer, in which photovoltaic solar cells were formed. One of the above-described methods is carried out at a plurality of separating surfaces T, four in the present case, and so five semiconductor components are available following singulation.

FIG. 3 illustrates a further schematic plan view from above on a silicon wafer, in which photovoltaic solar cells were formed, for the purposes of elucidating the exemplary embodiment as per FIG. 1B). The transverse conduction avoidance regions 5b, which are formed as separating trenches, are spaced apart from the edges of the semiconductor component, at a distance A of 1 mm. This leads to stabilization of the semiconductor wafer despite the fact that the separating trenches have a depth TG of 30% of the thickness of the semiconductor component. Prior to singulation of the semiconductor components, the separating trenches are formed up to the edges such that the ends of the separating trenches border the edges, the distance A consequently being 0. Subsequently, the singulation can be carried out in a simpler fashion, with a lower risk of defects since the above-described stabilization was neutralized by continuing the separating trenches.

List of Reference Signs

| | |
|---|---|
| 1a, 1b, 1c, 1d, 1e | Semiconductor component |
| 2a, 2b, 2c | Emitter |
| 2d1, 2e1 | TCO layer |
| 2d2, 2e2 | a-Si layer |
| 2d3, 2e3 | i-Si layer |
| 3a, 3b, 3c, 3d, 3e | Base |
| 4a, 4b, 4c | pn junction |
| 5a, 5b, 5c, 5d, 5e | Transverse conduction avoidance region |
| T | Separating surface |
| TQ | Transverse conduction avoidance region depth |
| TG | Separating trench depth |
| A | Distance from the edge |

What is claimed is:

1. A method for singulating a semiconductor component (1a, 1b, 1c, 1d, 1e) having a pn junction (4a, 4b, 4c), comprising the steps of:
A) providing a semiconductor component (1a, 1b, 1c, 1d, 1e) having at least one emitter (2a, 2b, 2c) and at least one base (3a, 3b, 3c, 3d, 3e), with a transverse conduction layer that is non-metallic and configured for transverse conduction of majority charge carriers of the emitter (2a, 2b, 2c), wherein at least one of a) a pn junction (4a, 4b, 4c) is formed between the emitter (2a, 2b, 2c) and the base (3a, 3b, 3c, 3d, 3e), and the emitter (2a, 2b, 2c) comprises the transverse conduction layer,
B) singulating the semiconductor component (1a, 1b, 1c, 1d, 1e) by separation into at least two partial elements at least one separating surface (T),
between method steps A and B, in a method step B0, forming a transverse conduction avoidance region (5a, 5b, 5c, 5d, 5e) in the transverse conduction layer in order to reduce transverse conductivity by at least a factor of 10 and wherein, in method step B, the separating surface (T) at least one of borders or passes through the transverse conduction avoidance region (5a, 5b, 5c, 5d, 5e),
the method further comprising forming the transverse conduction avoidance region (5a, 5b, 5c, 5d, 5e) as a separating trench which passes through the transverse conduction layer by at least half, wherein the separating trench is formed so as to pass through the pn junction (4a, 4b, 4c),
wherein the separating trench is formed by laser ablation,
wherein a post-treatment is carried out after the separating trench has been formed in order to reduce the surface recombination at the walls of the separating trench, at least in a region where the pn junction borders the separating trench,
wherein the post-treatment is implemented by wet chemical etching,
the method further comprising between method step B0 and B, in a method step B1, applying a passivation layer to the separating trench, said passivation layer at least covering the pn junction (4a, 4b, 4c) bordering the separating trench,
wherein in method step B, singulation is implemented by thermal laser separation or laser induced cutting.

2. The method as claimed in claim 1, wherein the separating trench has a depth (TG) which is at least 10% of a thickness of the semiconductor component.

3. The method as claimed in claim 1, wherein the separating trench is formed at a distance from edges of the semiconductor component, and in method step B, the separating trench is extended before the semiconductor component is singulated such that ends of the separating trench have a distance of less than 0.3 mm from the edges of the semiconductor component.

4. The method as claimed in claim 1, wherein at least one of the method step B0 is carried out after the emitter is formed or the method step B0 is carried out before one or more metallic contacting structures are applied.
